(19) United States
(12) Patent Application Publication
(10) Pub. No.: US 2025/0242369 A1
(43) Pub. Date: Jul. 31, 2025

(54) MASK MANUFACTURING DEVICE AND MANUFACTURING METHOD OF MASK USING THE SAME

(71) Applicant: SAMSUNG DISPLAY CO., LTD., YONGIN-SI (KR)

(72) Inventors: KYONGHO HONG, Yongin-si (KR); SUCKHO KANG, Yongin-si (KR); BONG SU KIM, Yongin-si (KR); WANSUB KIM, Yongin-si (KR); INWOO KIM, Yongin-si (KR); SUNG JIN NA, Yongin-si (KR); HEESEAK NOH, Yongin-si (KR); CHANG-KON PARK, Yongin-si (KR); HYUN MIN LEE, Yongin-si (KR); HYOGEUN LEE, Yongin-si (KR); DAUN JO, Yongin-si (KR)

(21) Appl. No.: 18/981,343

(22) Filed: Dec. 13, 2024

(30) Foreign Application Priority Data
Jan. 31, 2024 (KR) 10-2024-0015000

(51) Int. Cl. B05B 12/20; H10K 71/16

(52) U.S. Cl. CPC B05B 12/20; H10K 71/166

(57) ABSTRACT

A mask manufacturing device includes a stage for supporting a mask frame, and a guide disposed at a side of the mask frame, restricting a horizontal movement of the mask frame, and including a roller disposed at an end portion of the guide facing the mask frame.

### CROSS-REFERENCE TO RELATED APPLICATION

This application claims priority under 35 U.S.C. § 119 to Korean Patent Application No. 10-2024-0015000, filed on Jan. 31, 2024, in the Korean Intellectual Property Office, the content of which is incorporated by reference herein in its entirety.

### BACKGROUND

### 1. Technical Field

The present disclosure generally relates to a mask manufacturing device. More specifically, the present disclosure relates to a mask manufacturing device for manufacturing a display device and a manufacturing method of the mask using the same.

### 2. Discussion of Related Art

The significance display devices in connecting users with information is becoming increasingly apparent as information technology advances. Various types of display devices are widely used across different fields. These include liquid crystal displays (LCDs), organic light-emitting displays (OLEDs), plasma displays (PDPs), and quantum dots displays.

The manufacture a light-emitting element (e.g., an organic light-emitting element) included in the display device typically uses a mask to control a deposition of material which forms the light-emitting element. Variations in a position of the mask may affect an accuracy of the deposition.

### SUMMARY

An embodiment of the present disclosure provides a mask manufacturing device with improved manufacturing precision.

An embodiment of the present disclosure provides a manufacturing method of a mask using a mask manufacturing device.

A mask manufacturing device according to an embodiment of the disclosure includes a stage for supporting a mask frame, and a guide disposed at a side of the mask frame, restricting a horizontal movement of the mask frame, and including a roller disposed at an end portion of the guide facing the mask frame.

In an embodiment, the roller may include a ball caster.

In an embodiment, the mask frame may include a first side, a second side parallel to the first side, a third side crossing both the first side and the second side, and a fourth side parallel to the third side, and the guide may include a first guide disposed adjacent to the first side, a second guide disposed adjacent to the second side, a third guide disposed adjacent to the third side, and a fourth guide disposed adjacent to the first side.

In an embodiment, the first guide and the second guide may restrict a movement of the mask frame in a first direction within a first predetermined gap, and the third guide and the fourth guide may restrict a movement of the mask frame in a second direction crossing the first direction within a second predetermined gap.

In an embodiment, a plurality of air holes may be defined in the stage for directing air to the mask frame and for levitating the mask frame above the stage.

In an embodiment, the device may further include an alignment camera disposed above the stage.

In an embodiment, the alignment camera may be configured to check an alignment of the mask frame while the mask frame is levitated.

In an embodiment, a stick mask may be disposed on the mask frame wherein the stick mask may include a pattern portion on which a plurality of cell regions may be defined, and a dummy portion surrounding the pattern portion.

A mask manufacturing device according to an embodiment includes a stage having a plurality of air holes disposed in an edge portion of an upper surface of the stage, a plurality of guides disposed overlapping a plurality of sides of the stage and forming a restrictive space above the stage, and a plurality of rollers disposed at end portions of the plurality of guides and facing the restrictive space.

In an embodiment, the rollers each include a ball caster.

In an embodiment, an alignment camera may be disposed above the stage, wherein the alignment camera is configured to check an alignment of the mask frame while the mask frame is levitated within a restrictive space.

A manufacturing method of a mask according to an embodiment of the disclosure includes disposing a mask frame on a stage in which air hole is defined, levitating the mask frame above the stage by air exiting from the air hole, and restricting a horizontal movement of the mask frame by a guide disposed on a side of the mask frame and including a roller disposed at an end portion of the guide facing the side of the mask frame.

In an embodiment, the roller may include a ball caster rolling in contact with the mask frame.

In an embodiment, the mask frame may include a first side, a second side parallel to the first side, a third side crossing both the first side and the second side, and a fourth side parallel to the third side, and the guide may include a first guide disposed adjacent to the first side, a second guide disposed adjacent to the second side, a third guide disposed adjacent to the third side, and a fourth guide disposed adjacent to the first side, wherein the method may further include directing the air from a plurality of holes, including the air hole, defined in the stage, to each of the first side, the second side, the third side, and the fourth side of the mask frame.

In an embodiment, a method may further include restricting, by the first guide and the second guide, a movement of the mask frame in a first direction within a first predetermined gap, and restricting, by the third guide and the fourth guide, a movement of the mask frame in a second direction crossing the first direction within a second predetermined gap.

In an embodiment, the method may further include checking an alignment of the mask frame after levitating the mask frame above the stage.

In an embodiment, the alignment of the mask frame may be checked by an alignment camera, and the guide is disposed so that the mask frame may be positioned within an imaging area of the alignment camera.

In an embodiment, the method may further include seating a stick mask on the mask frame after restricting the horizontal movement of the mask frame.

In an embodiment, the method may further include welding the stick mask to the mask frame after seating the stick mask on the mask frame.

In an embodiment, a position of the guide may be maintained following a welding of the stick mask to the mask frame.

A manufacturing device of a mask according to an embodiment of the disclosure may include a stage on which the mask frame is disposed, and a guide disposed on a side of the mask frame, restricting a horizontal movement of the mask frame, and including a roller disposed at an end portion of the guide facing the side of the mask frame. As the movement of the mask frame may be restricted by the guide, the manufacturing precision of the mask may be improved. In addition, as the guide includes the roller, friction by the guide may be reduced or eliminated when aligning the mask frame.

In addition, the air hole may be defined in the stage, and air exiting from the air hole may levitate the mask frame. As the mask frame is levitated above the stage, friction between the stage and the mask frame may be reduced or eliminated, and an effect of the flatness of an upper surface (i.e., seating surface) of the stage may be reduced or eliminated. Accordingly, the manufacturing precision of the mask may be improved, and air pocket to reduce the effect by the flatness might not be formed in the mask frame.

In addition, as the alignment is performed by the guide, the alignment of the mask frame may be checked while the mask frame is levitated. Accordingly, the manufacturing precision of the mask may not deteriorate due to the mask frame moving within or escaping the imaging area of the alignment camera.

A manufacturing method of a mask according to an embodiment of the disclosure may include disposing a mask frame on a stage in which air hole is defined, levitating the mask frame from the stage by air exiting from the air hole, and restricting a horizontal movement of the mask frame by a guide disposed on a side of the mask frame and including a roller disposed at an end portion of the guide facing the side of the mask frame. As the mask frame is levitated on the stage, the friction between the stage and the mask frame may be reduced or eliminated, an effect of the flatness of the upper surface of the stage may be reduced or eliminated, and an air pocket to reduce the effect by the flatness may be omitted from the mask frame. In addition, as the guide includes the roller, friction by the guide may be reduced or eliminated when aligning the mask frame.

In addition, a manufacturing method of a mask may further include checking the alignment of the mask frame after levitating the mask frame from the stage. The alignment of the mask frame may be checked by the alignment camera, and the guide may be disposed so that the mask frame may be positioned within the imaging area of the alignment camera. Accordingly, the manufacturing precision of the mask may be maintained due to the mask frame, and the mask frame may not move within or escape the imaging area of the alignment camera.

In addition, the guide may continue to restrict the horizontal movement of the mask frame even after the stick mask is welded to the mask frame. Accordingly, the manufacturing precision of the mask may be maintained.

### BRIEF DESCRIPTION OF THE DRAWINGS

The accompanying drawings, which are included to provide a further understanding of the present invention, illustrate embodiments of the present disclosure together with the description thereof, in which:

FIG. 1 is a side view of a mask manufacturing device according to an embodiment of the present disclosure.

FIG. 2 is an enlarged view of an A region of FIG. 1.

FIG. 3 is a view illustrating a roller according to an embodiment included in a mask manufacturing device of the mask of FIG. 1.

FIG. 4 is a plan view of a mask manufacturing device of FIG. 1.

FIG. 5 is an enlarged view of a B region of FIG. 4.

FIG. 6 is a view illustrating an effect of a mask manufacturing device.

FIG. 7 is a view illustrating a deposition device on which a mask according to an embodiment manufactured by a mask manufacturing device of FIG. 1.

FIG. 8 is a view illustrating a mask disposed in a deposition device of FIG. 7.

FIG. 9 is a view illustrating a pixel manufactured by a deposition device of FIG. 7.

FIG. 10, FIG. 11, FIG. 12, FIG. 13, and FIG. 14 are views illustrating a manufacturing method of a mask using a mask manufacturing device of the mask of FIG. 1.

### DETAILED DESCRIPTION

Illustrative, non-limiting embodiments of the present disclosure will be more clearly understood from the following detailed description in conjunction with the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. Like reference numerals or symbols refer to like elements throughout.

In the drawings, the thicknesses, the ratios, and the dimensions of the elements may be exaggerated for effective description of the technical contents.

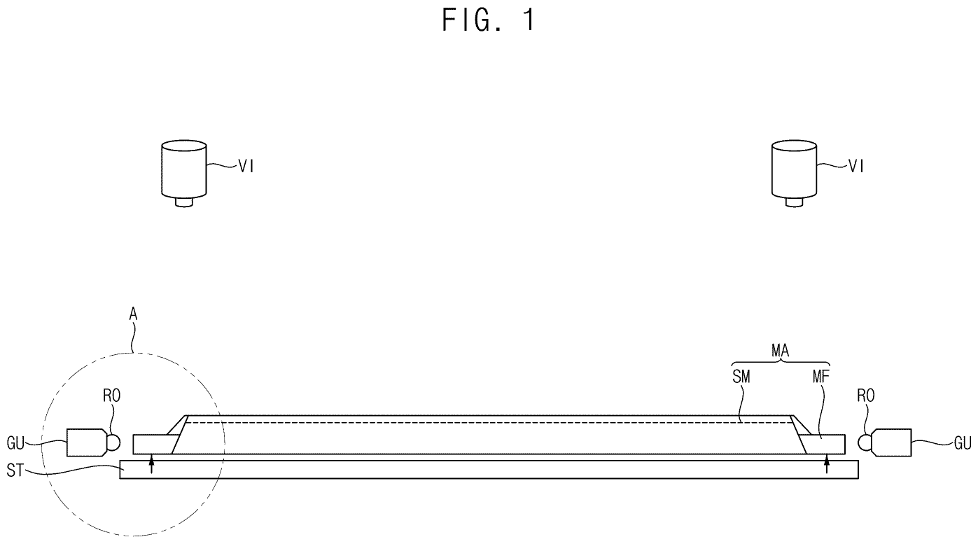

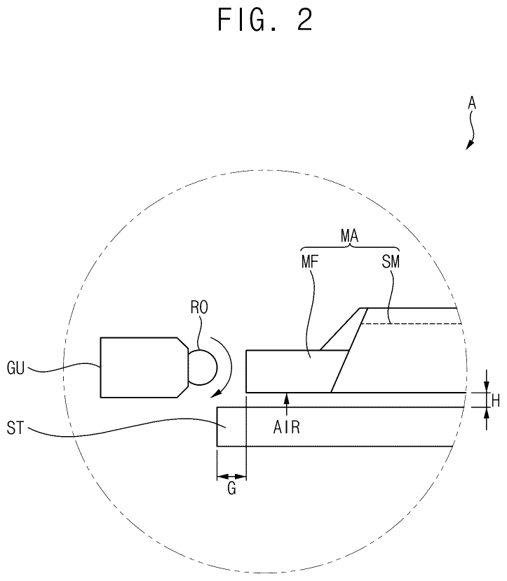

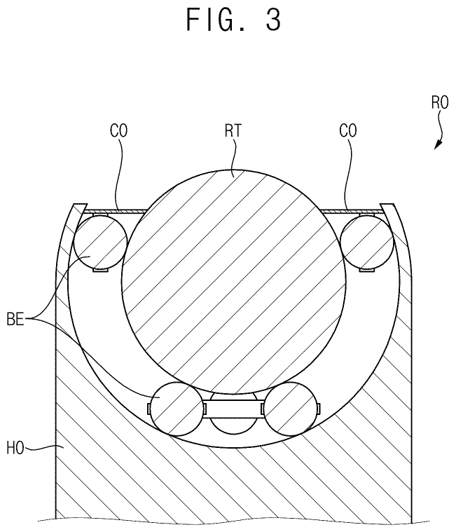

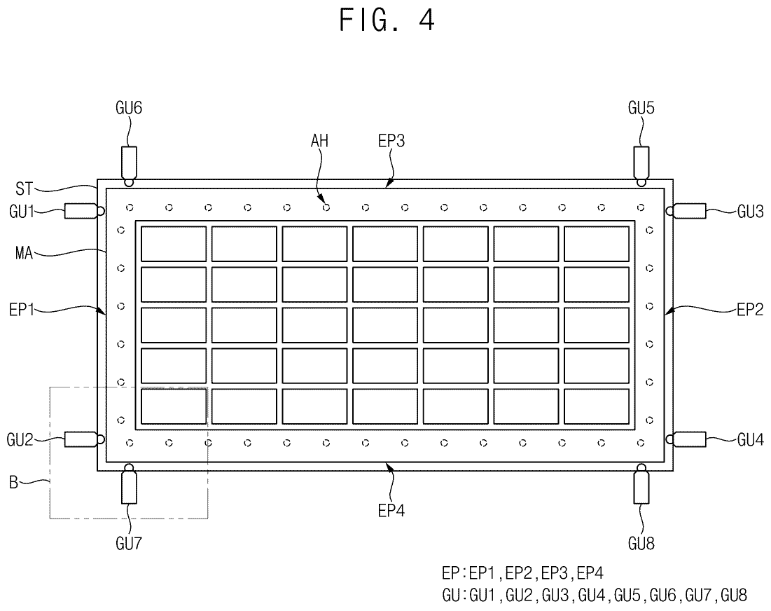

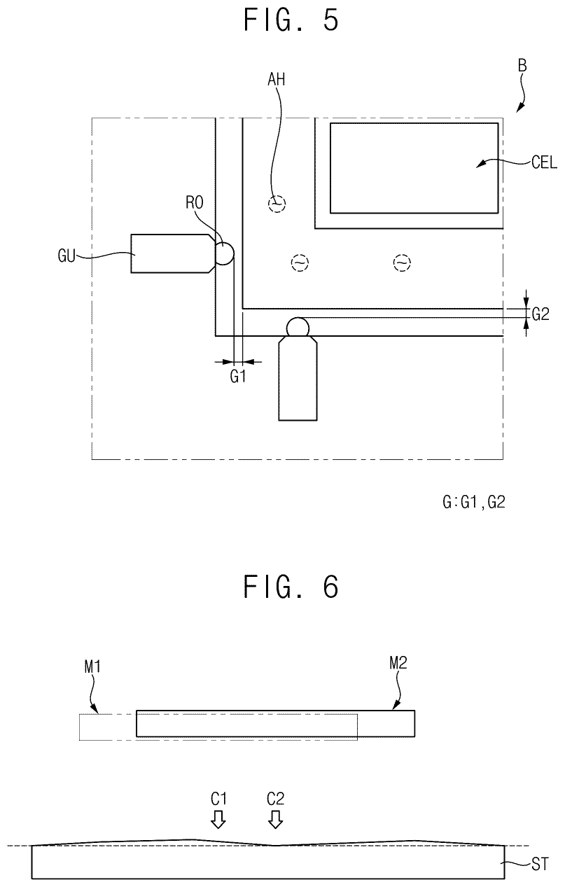

FIG. 1 is a side view of a mask manufacturing device according to an embodiment of the present disclosure. FIG. 2 is an enlarged view of an A region of FIG. 1. FIG. 3 is a view illustrating a roller according to an embodiment included in the mask manufacturing device of FIG. 1. FIG. 4 is a plan view of the mask manufacturing device of FIG. 1. FIG. 5 is an enlarged view of a B region of FIG. 4.

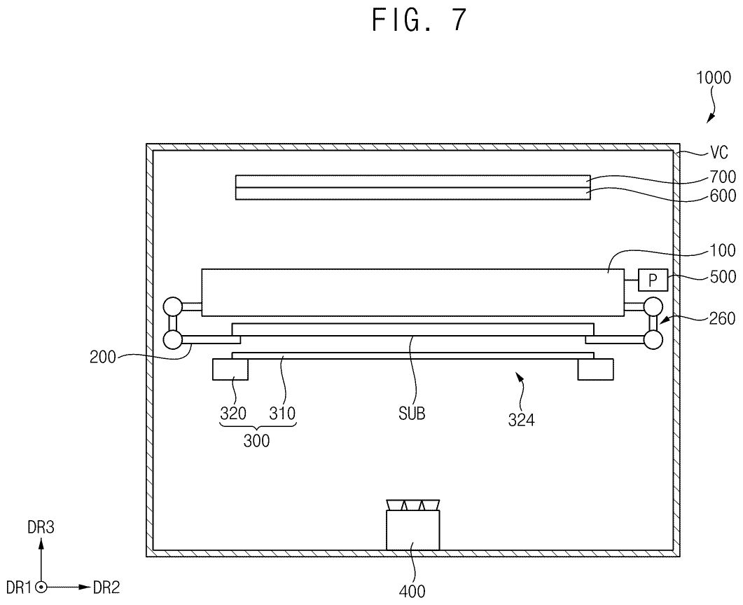

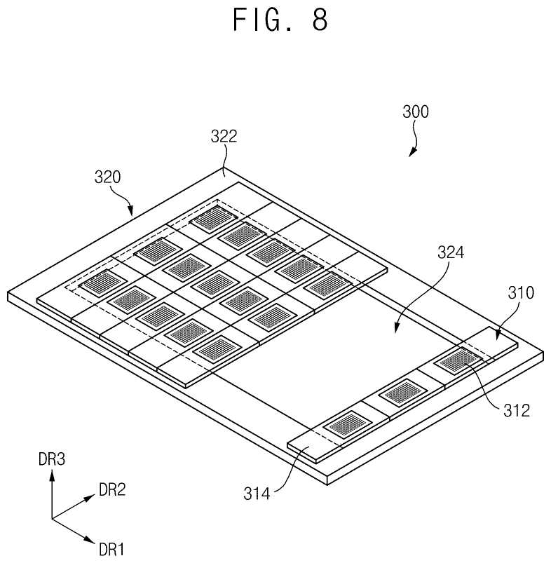

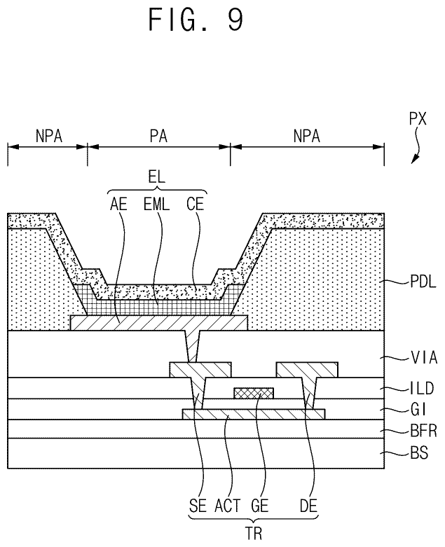

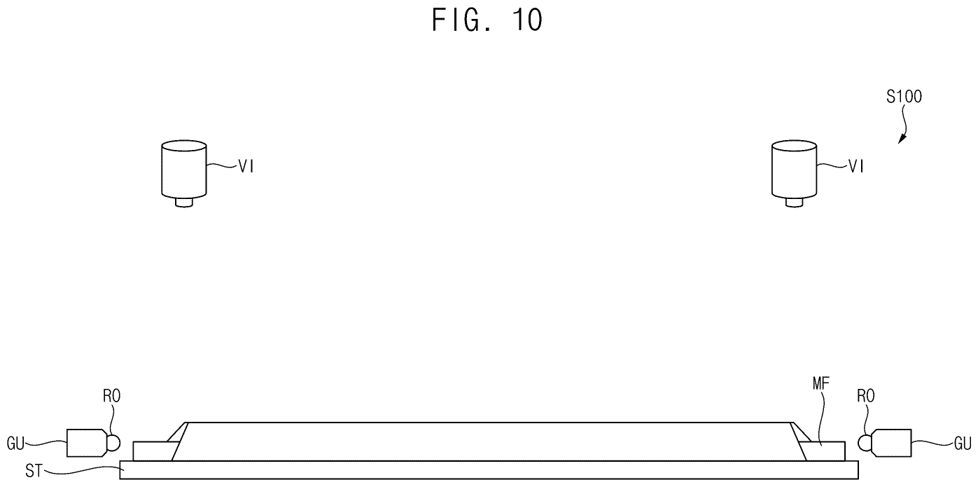

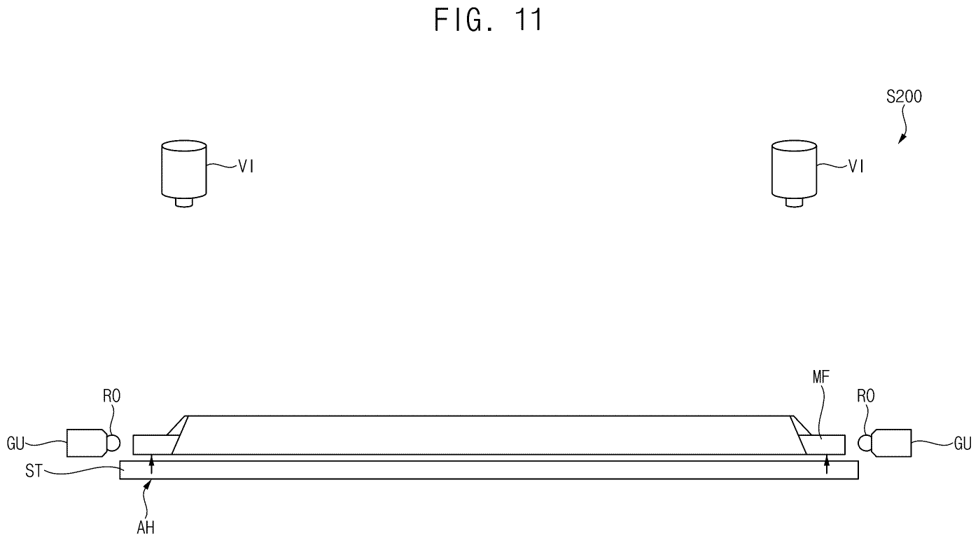

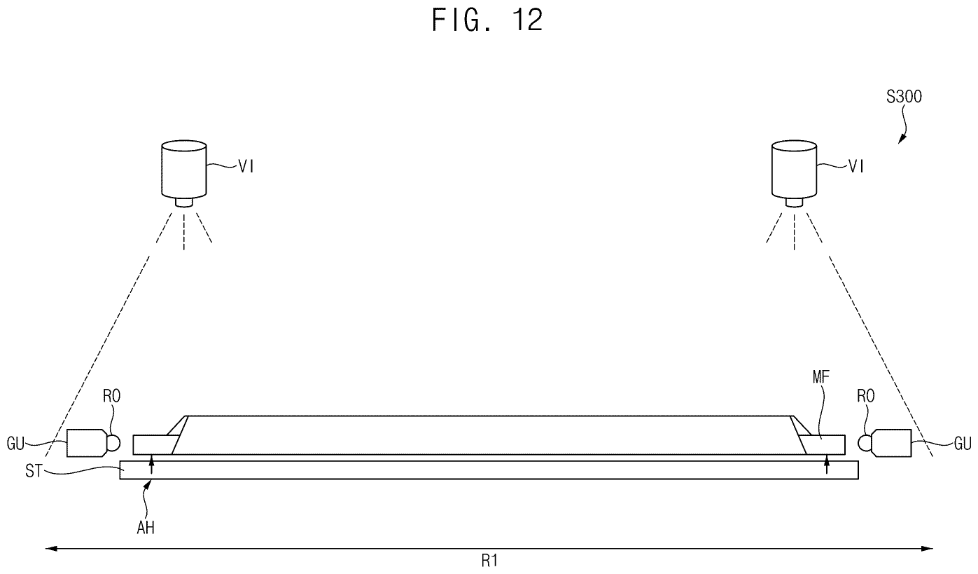

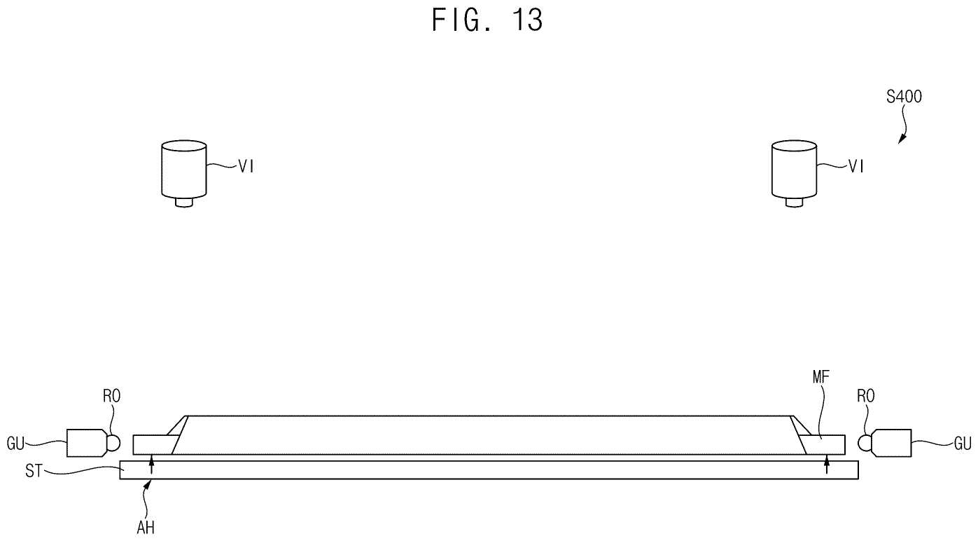

Referring to FIG. 1 through FIG. 5, a mask manufacturing device according to an embodiment may include a stage ST, a guide GU, and an alignment camera VI. The mask manufacturing device may manufacture a mask MA. The mask MA may be used in a deposition process to from a pixel (e.g., a pixel PX of FIG. 9) included in a display device. The deposition process may be a process of depositing a material on a substrate (e.g., a substrate BS of FIG. 9). The mask MA may include a pattern of openings that may allow a portion of the deposition material to pass through the mask MA and be deposited on a substrate. A detailed description of the mask MA and a deposition process using the mask MA will be provided herein with reference to FIG. 7, FIG. 8, and FIG. 9.

In an embodiment, the mask frame MF may be disposed on the stage ST. For example, the stage ST may be configured for supporting the mask frame MF. For example, the stage ST may have a seating surface defined by a first direction and a second direction. For example, the second direction may cross the first direction. The first direction (DR1) and the second direction (DR2) may form a plane, which may be a horizontal plane. The mask frame MF may be seated on the seating surface.

In an embodiment, as depicted in FIG. 4, an air hole AH may be defined in the stage ST. Air exiting the air hole AH in the stage ST may provide a force to levitate the mask frame MF about the stage ST. For example, the air may be directed in a third direction (DR3). The third direction may cross both the first direction and the second direction. For example, the third direction may be perpendicular to the first direction and the second direction, and may be a vertical direction.

In an embodiment, the air hole AH may be formed in an edge portion the stage ST. A plurality of air holes AH may be formed in an edge portion of a long side and a short side of the stage ST. An opening may be defined in a center portion of the mask frame MF (refer to FIG. 8). Air may pass through the opening. The air hole AH may be defined in the stage ST overlapping the edge portion of the mask frame MF. The air hole AH may be omitted from an area of the stage ST overlapping the opening.

The air may provide a force to space the mask frame MF from the stage ST in the third direction. For example, the mask frame MF may levitate, by the air, by a certain height (e.g., H of FIG. 2) from the stage ST. For example, the mask frame MF may use the force of air to float above the stage in the third direction.

In an embodiment, the stage ST may include an air providing system. For example, the air providing system may be an air pump such as an air compressor or a reciprocating pump, or a compressed air cylinder. The air providing system may provide an air flow to the air hole AH. An air pipe may connect the stage ST and the air providing system. A controller may control at least one of the flow of air or the discharge amount of the air.

In an embodiment, a plurality of air holes AH may be disposed in the edge portion of the stage ST. For example, the air holes AH of the plurality of air holes AH may be disposed at regular intervals in the edge portion of the stage ST. Accordingly, the air holes AH may provide the air uniformly, and the mask frame MF may be levitated having a uniform height in the third direction.

While levitating (air floating), the mask frame MF may deviate from an intended position. For example, even if a first center of the stage ST and a second center of the mask frame MF are aligned at a first time, the first center of the stage ST and the second center of the mask frame MF may be subsequently misaligned once the mask frame MF is levitated.

In an embodiment, the guide GU may be disposed at a side EP of the mask frame MF. The guide GU may compensate for a positional error of the mask frame MF. The guide GU may compensate for a positional error of the mask frame MF due to the levitating. For example, the guide GU may restrict horizontal movement of the mask frame MF.

In an embodiment, the mask frame MF may have a rectangular shape. In an embodiment, the mask frame MF may include a first side EP1, a second side EP2, a third side EP3, and a fourth side EP4. The second side EP2 may be substantially parallel to the first side EP1. The third side EP3 may cross the first side EP1 and the second side EP2. For example, the third side EP3 may be substantially perpendicular to the first side EP1 and the second side EP2. The fourth side EP4 may be substantially parallel to the third side EP3. For example, the fourth side EP4 may be perpendicular to the first side EP1 and the second side EP2.

In an embodiment, a plurality of guides GU may be provided. In an embodiment, the plurality of guides GU may include a first guide GU1, a third guide GU3, a fifth guide GU5, and a seventh guide GU7. The first guide GU1 may adjacent to the first side EP1 of the mask frame MF. The third guide GU3 may adjacent to the second side EP2 of the mask frame MF. The fifth guide GU5 may adjacent to the third side EP3 of the mask frame MF. The seventh guide GU7 may adjacent to the fourth side EP4 of the mask frame MF. For example, the plurality of guides GU may include at least one guide GU provided at each side of the mask frame MF.

For example, as depicted in FIG. 4, the plurality of guides GU may be disposed at the side EP of the mask frame MF. For example, the first guide GU1 and the second guide GU2 may be disposed at the first side EP1 of the mask frame MF. The first guide GU1 and the second guide GU2 may be disposed at opposite sides of the first side EP1 of the mask frame MF. The third guide GU3 and the fourth guide GU4 may be disposed at the second side EP2 of the mask frame MF. The third guide GU3 and the fourth guide GU4 may be disposed at opposite sides of the second side EP2 of the mask frame MF. The fifth guide GU5 and the sixth guide GU6 may be disposed at the third side EP3 of the mask frame MF. The fifth guide GU5 and the sixth guide GU6 may be disposed at opposite sides of the third side EP3 of the mask frame MF. The seventh guide GU7 and the eighth guide GU8 may be disposed at the fourth side EP4 of the mask frame MF. The seventh guide GU7 and the eighth guide GU8 may be disposed at opposite sides of the fourth side EP4 of the mask frame MF.

In an embodiment, as depicted in FIG. 4, the plurality of guides GU may be disposed above and at sides of the stage ST. For example, the first guide GU1 and the second guide GU2 may be disposed at a first side of the stage ST corresponding to the first side EP1 of the mask frame MF. The third guide GU3 and the fourth guide GU4 may be disposed at a second side of the stage ST corresponding to the second side EP2 of the mask frame MF. The fifth guide GU5 and the sixth guide GU6 may be disposed at a third side of the stage ST corresponding to the third side EP3 of the mask frame MF. The seventh guide GU7 and the eighth guide GU8 may be disposed at a fourth side of the stage ST corresponding to the fourth side EP4 of the mask frame MF. Portions of the guides GU may overlap with an upper surface of the stage ST. The guides GU may form a restrictive space above the stage ST for restricting horizontal movement of the mask frame MF.

However, the disclosure is not limited thereto. For example, three or more guides GU may be disposed on the sides EP of the mask frame MF. As another example, one guide GU may be disposed on the side EP of the mask frame MF. In yet another example, different numbers of guides GU may be provided at different sides EP of the mask frame MF.

The guide GU may restrict the horizontal movement of the mask frame MF (e.g., the movement in the first direction and/or the movement in the second direction). In an embodiment, the first guide GU1 and the third guide GU3 may restrict the movement of the mask frame MF in the first direction, and the fifth guide GU5 and the seventh guide GU7 may restrict the movement of the mask frame MF in the second direction.

For example, the guide GU may restrict the horizontal movement of the mask frame MF (e.g., the movement in the first direction and/or the movement in the second direction) within a predetermined gap G. For example, as depicted in FIG. 4 and FIG. 5, the second guide GU2 may allow the movement of the mask frame MF within a first gap G1, and the seventh guide GU7 may allow the movement of the mask frame MF within a second gap G2.

However, the disclosure is not limited thereto. For example, as depicted in FIG. 5, a size the first gap G1 and a size of the second gap G2 may differ, however, the size of the first gap G1 and the size of the second gap G2 may be a same.

In addition, a size of the gap G that allows the movement of the mask by the guide U may be variously changed depending on, for example, the manufacturing precision of the mask MA.

For another example, the first guide GU1 and the third guide GU3 may restrict the movement of the mask frame MF in the second direction within the predetermined gap, and the fifth guide GU5 and the seventh guide GU7 may restrict the movement of the mask frame MF in the first direction.

In an embodiment, the guide GU may include a friction reduction device. The friction reduction device may be disposed at the end portion of the guide GU facing the side of the mask frame MF.

In an embodiment, the guide GU may include a roller RO. The roller RO may be disposed at the end portion of the guide GU facing the side of the mask frame MF.

In an embodiment, the roller RO may include a ball caster. For example, as depicted in FIG. 3, the ball caster may include a housing HO, a plurality of bearings BE, a rotating body RT, and a cover CO. For example, a seating groove may be defined in the housing HO. The seating groove may be a semicircular seating groove. The rotating body RT may be accommodated in the seating groove. The plurality of bearings BE may be disposed between the rotating body RT and the housing HO. The cover CO may be disposed at an opening of the housing HO. The cover CO may be disposed between the housing HO and the rotating body RT. The cover may prevent a departure of the rotating body RT and/or the plurality of bearings BE from the housing HO. The cover may expose a portion of the rotating body RT to the opening of the housing HO. When the rotating body RT rotates, one of more of the plurality of bearings BE may rotate in the housing HO, and reduce a frictional resistance between the rotating body RT and the housing HO.

However, the disclosure is not limited thereto. For example, the plurality of bearings BE and/or the cover CO may be omitted.

For example, the roller RO may include a variety of components, and a structure of the ball caster may be changed variously.

In an embodiment, the friction reduction device may include air flow device. The air flow device may use the pressure of an air flow to align the mask frame MF in a non-contact manner by directing a flow of air on the side EP of the mask frame MF. Accordingly, friction due to contact alignment may be reduced.

Referring to FIG. 1 again, in an embodiment, an alignment camera VI may be directed at the mask frame MF. In an embodiment, the alignment camera VI may be disposed on the mask frame MF. The alignment camera VI may be disposed to capture an image of the mask frame MF. The alignment camera VI may check the alignment of the mask frame MF using various methods. For example, the alignment camera VI may check a position the mask frame MF against an alignment mark disposed on the stage ST. In another example, the alignment camera VI may check a position the mask frame MF against an alignment mark disposed on the lens of the alignment camera VI. In yet another example, the alignment camera VI may check a position the mask frame MF using imaging software. However, methods of checking an alignment of the mask frame MF according to embodiments of the disclosure are not limited thereto.

In an embodiment, the alignment camera VI may check the alignment of the mask frame MF (e.g., position coordinates or relative positioning) while the mask frame MF is levitated.

For example, the mask frame MF may include an align mark. The alignment camera VI may check the alignment of the mask frame MF by capturing an image of the alignment mark.

A mask manufacturing device may be used to manufacture the mask MA. In an embodiment, the mask MA may include a mask frame MF and a stick mask SM.

In an embodiment, the stick mask SM may be disposed on the mask frame MF.

In an embodiment, the stick mask SM may include a pattern portion (e.g., a pattern portion 312 of FIG. 8). The pattern portion may define a plurality of cell regions CEL and a dummy portion (e.g., a dummy portion 314 of FIG. 8). The dummy portion may be disposed to surround the pattern portion. A detailed description of the pattern portion and the dummy portion may be described herein with reference to FIG. 8.

The stick mask SM may be fixed to the mask frame MF. In an embodiment, a portion of the stick mask SM may be welded to the mask frame MF. For example, end portions of the stick mask SM may be welded to the mask frame MF.

When fixing the stick mask SM to the mask frame MF, a portion of the stick mask SM may sag in a gravity direction. In a case that the stick mask SM is fixed to the mask frame MF in a sagging state, precision of the mask MA may be decreased. To improve the precision of the mask MA, the stick mask SM may be fixed to the mask frame MF while the stick mask SM is held in a tensioned state. At this time, the tension of the stick mask SM may be transferred to the mask frame MF. When attaching a stick mask SM, a position of the mask frame MF may have been changed due to the tensile force of a previously attached stick mask SM. In an embodiment, the change in position of the mask frame MF may be compensated for by levitating the mask frame MF and checking an alignment of the mask frame MF using the alignment camera VI. For example, an alignment of the mask frame MF may be checked prior to the fixing of each stick mask SM. For example, the mask frame MF may be levitated prior to the fixing of each stick mask SM.

A residual tension may remain in a case that the mask frame MF is not levitated, wherein a residual tension may be maintained by friction between the mask MA and the mask stage ST. If the change in position cannot be checked, the change due to the tension may not be compensated, which may affect the manufacturing precision of the mask MA.

The mask manufacturing device according to an embodiment may levitate the mask frame MF to relive the friction and substantially prevent a residual tension.

In a case that the mask frame MF is levitated, a position of the mask frame MF may shift, and the mask frame may move from an imaging area of the alignment camera VI. In order to reduce or prevent a shift in the position of the mask frame MF, the mask manufacturing device according to an embodiment may include the guide GU. The guide GU may be set considering a manufacturing tolerance of the mask frame MF and the imaging area of the alignment camera VI.

In a case that the mask frame MF moves while levitated, the mask frame MF may contact the guide GU. Friction may be generated between the side of the guide GU and the side of the mask frame MF. The friction may impart a tension to the mask frame MF, and the tension may affect the manufacturing precision of the mask MA. In an embodiment, the roller RO may reduce or eliminate the friction between the mask frame MF and the guide GU, which may reduce or eliminate the tension. For example, the roller RO may be included on the side of the guide GU. In an embodiment, the roller RO may include the ball caster.

FIG. 6 is a view illustrating an effect of the mask manufacturing device.

Referring to FIG. 6, the seating surface of the stage ST might not be flat. For example, a first mask M1 may be fixed to a mask frame MF at a first position C1 of the stage ST. Next, a second mask M2 whose center may be aligned with a second position C2 of the stage ST may be fixed to the to the mask frame MF. A level of the first position C1 of the stage ST may be greater than a level of the second position C2 of the stage ST in the third direction.

A mask manufacturing device according to a comparative embodiment, the stick mask may be disposed on the mask frame MF in contact with the stage ST and then the stick mask may be fixed to the mask frame. In this case, the first mask M1 may be manufactured at a greater level than the second mask M2, and the tolerance of the mask manufacturing due to a level difference may occur.

The tolerance of the mask manufacturing may affect a deposition precision in the deposition process using the mask. For example, as the tolerance of the mask manufacturing is increases, defects (e.g., a dark spot, mixed colors, or the like) may be more likely to occur in the display device. These defects may be generated during a deposition of the deposition material, where the deposition material may be deposited at a position outside a position where the pixel (e.g., the pixel PX of FIG. 9) should be formed in the deposition process.

According to an embodiment of the disclosure, the stick mask may be disposed on the mask frame in the non-contact state, and the stick mask may be fixed on the mask frame. By reducing or removing contact with the seating surface of the stage ST, an effect of the flatness of the seating surface of the stage ST may be reduced or removed and the tolerance of the mask manufacturing may be reduced. In other words, as the mask frame is levitated above the stage ST, friction between the stage ST and the mask frame may be reduced or eliminated, and the effect of the flatness of the seating surface of the stage ST may be removed.

In a case of a mask manufacturing device according to an embodiment, the mask frame may be levitated by the air exiting from the air hole (e.g., the air hole AH of FIG. 2) of the stage ST. For example, the mask frame MF may omit a structure, e.g., a groove formed on a lower surface of the mask frame MF, for creating an air pocket therein. For example, the mask frame MF may have a substantially planar lower surface. In this case, a process of forming the air pocket on the mask frame may be omitted, and a manufacturing cost, time, or the like may be improved. In addition, variations due to the air pocket in the mask frame MF may be reduced or eliminated.

In the case of the mask manufacturing device according to an embodiment of the disclosure, as depicted in FIG. 1, the tolerance of the mask manufacturing may be improved by levitating the mask frame MF using air exiting from the stage ST. In addition, the tolerance of the mask manufacturing may be improved by restricting a degree of freedom of the mask frame MF in the horizontal direction by the guide GU. In other words, in the case of the mask manufacturing device according to an embodiment of the disclosure, the manufacturing precision of the mask may be improved by reducing or removing contact with surrounding structures. and the air pocket might not be formed in the mask frame.

FIG. 7 is a view illustrating a deposition device implementing a mask according to an embodiment manufactured using the mask manufacturing device of FIG. 1. FIG. 8 is a view illustrating a mask disposed in the deposition device of FIG. 7.

Referring to FIG. 7 and FIG. 8, a deposition device 1000 may include an electrostatic chuck 100, a mask unit 300, a deposition source 400, a cooling plate 600, and a magnetic plate 700 disposed within a vacuum chamber VC.

The vacuum chamber VC may provide an airtight space, and a deposition condition may be set to vacuum. The vacuum chamber VC may include a top surface, a bottom surface, and side surfaces. The bottom surface may face the top surface in the third direction DR3. Each of the side surfaces may be perpendicularly connected to the top and bottom surfaces. At least one opening may be disposed in a surface of the vacuum chamber VC. For example, the opening may be controlled by a gate or a door, which may be used to maintain the airtight space. A substrate SUB may enter and exit the vacuum chamber VC through the opening.

The electrostatic chuck 100 may be disposed inside the vacuum chamber VC. A driving unit may be disposed between the electrostatic chuck 100 and the vacuum chamber VC. The electrostatic chuck 100 may move in the third direction DR3 or in a direction opposite to the third direction DR3 by an operation of the driving unit. For example, the electrostatic chuck 100 may move vertically by the operation of the driving unit.

The electrostatic chuck 100 may include a housing, and multiple electrodes disposed inside the housing. The electrodes may include first and second electrodes having different polarities. For example, the first electrodes may have a positive polarity (+) and the second electrodes may have a negative polarity (−).

The electrodes may be alternately arranged in the first direction DR1 and/or the second direction DR2. For example, the electrodes may be alternately arranged in the second direction DR2. Alternatively, the electrodes may be alternately arranged in the first direction DR1. Alternatively, the electrodes may be arranged diagonally (e.g., the direction crossing the second direction DR2 and the third direction DR3).

The electrostatic chuck 100 may overlap the substrate SUB in a plan view. The electrostatic chuck 100 may entirely overlap the substrate SUB in the plan view. Accordingly, the substrate SUB may be inhibited or prevented from sagging in the direction opposite to the third direction DR3 while deposition materials provided from the deposition source 400 are deposited.

The electrostatic chuck 100 may chuck or dechuck the substrate SUB by an electrostatic force. The electrostatic chuck 100 may be a bipolar electrostatic chuck or a monopolar electrostatic chuck. In a case of a bipolar electrostatic chuck 100, the electrostatic chuck 100 may include a plurality of electrode plates. For example, in a case that a voltage is applied between two electrode plates, the substrate SUB may be chucked. In a case of a monopolar electrostatic chuck 100, the electrostatic chuck 100 may include one or more electrode plates. In case that a voltage is applied between the one or more electrode plates and the substrate SUB, the substrate SUB may be chucked. After a deposition process is performed, the electrostatic chuck 100 may dechuck the substrate SUB.

The electrostatic chuck 100 may have a multilayer structure. For example, the electrostatic chuck 100 may include a base layer, an insulating layer, and an electrode. The base layer may include a material for providing a chucking surface capable of chucking or dechucking the substrate SUB. For example, the base layer may include ceramic, aluminum, titanium, stainless steel, alumina, yttrium oxide, or aluminum nitride. These example materials may be used alone or in combination with each other. The insulating layer may include a material having high heat resistance and high chemical stability. For example, the insulating layer may include yttrium oxide or alumina. As a voltage is applied to the electrode, the substrate SUB may be chucked or dechucked by the electrostatic chuck 100. However, the electrostatic chuck 100 according to embodiments of the disclosure is not limited thereto.

A holder 200 may be disposed between the electrostatic chuck 100 and the mask frame 320. The holder 200 may secure the substrate SUB.

A first end of the holder 200 may be connected to a side of the electrostatic chuck 100. Accordingly, the electrostatic chuck 100 and the holder 200 may move simultaneously.

For example, the holder 200 may linearly move in the third direction DR3, or the direction opposite to the third direction DR3. However, the electrostatic chuck 100 according to embodiments of the disclosure is not limited thereto. The holder 200 may include additional connecting part, and the connecting parts may move linearly or rotationally.

The mask unit 300 may be disposed under the electrostatic chuck 100. For example, the mask unit 300 may be disposed under the holder 200.

The mask unit 300 of FIG. 7 may be an embodiment of the mask MA manufactured by the mask manufacturing device of FIG. 1. In other words, the mask frame MF of FIG. 1 may correspond to the mask frame 320 of FIG. 8, and the stick mask SM of FIG. 1 may correspond to the stick mask 310 of FIG. 8.

The mask unit 300 may include a stick mask 310 and a mask frame 320. The mask unit 300 may be disposed under the electrostatic chuck 100. For example, the mask unit 300 may be disposed under the holder 200.

In an embodiment, the stick mask 310 may include the pattern portion 312 on which the plurality of cell regions (e.g., the plurality of cell regions of FIG. 5) may be defined and the dummy portion 314 disposed adjacent to the pattern portion 312. For example, the dummy portion 314 may surround the pattern portion 312.

Multiple holes may be formed in the pattern portion 312. The holes may be, for example, slits. The deposition materials may be provided to the substrate SUB through the openings. The cell regions may be spaced apart from each other. The cell regions may be arranged in one of the first direction DR1 or the second direction DR2, or may be arranged in a matrix form in the first direction DR1 and the second direction DR2. However, the disclosure is not limited thereto.

The mask frame 320 may be disposed under the electrostatic chuck 100. For example, the mask frame 320 may be disposed under the holder 200.

In an embodiment, the stick mask 310 may be seated on the mask frame 320. In an embodiment, the stick mask 310 may be seated on an upper surface 322 of the mask frame 320. In an embodiment, the stick mask 310 may be fixed to the upper surface 322 the mask frame 320. For example, the stick mask 310 may be welded to the mask frame 320.

An opening 324 may be disposed at a middle portion of the mask frame 320. The opening 324 may have a rectangular shape. The opening 324 in the mask frame 320 may define an edge portion of the mask frame 320. The stick mask 310 may be disposed on the mask frame 320 such that the holes formed on the stick mask 310 overlap the opening 324 formed in the mask frame 320 in the thickness direction of the mask frame 320, that is the third direction DR3.

The mask frame 320 may include a metal. For example, the metal may include stainless steel, an invar alloy, nickel, or cobalt. These materials may be used alone or in combination with each other.

The deposition source 400 may be disposed under the mask unit 300.

The deposition source 400 may supply a deposition material. The deposition source 400 may include a heating source and at least one nozzle for supplying the deposition material.

The deposition source 400 may provide a deposition material to be deposited on the substrate SUB. According to an embodiment, the deposition material may include a metal, an organic material, or an inorganic material. For example, in case that the deposition material is an organic material, an organic material layer may be formed through a deposition process.

The deposition material may include a vaporization material or a sublimation material. In case that the deposition material is a vaporization material, the heating source may be disposed adjacent to the deposition material. The heating source may heat and vaporize the deposition material. In an embodiment, the heating source may be omitted.

The nozzle may be disposed over the deposition material. The nozzle may spray the deposition material in the first direction DR1. At least one nozzle may be provided. In an embodiment, a plurality of nozzles may be provided. The nozzles may be spaced apart from each other in the first direction DR1 and/or the second direction DR2. A number, an interval, a shape, and the like of the nozzles may vary depending on the deposition material.

A power supply 500 may be connected to the electrostatic chuck 100. For example, the power supply 500 may be connected to the electrodes of the electrostatic chuck 100. For example, the power supply 500 may include a first terminal defined as a positive electrode and a second terminal defined as a negative electrode. The first electrodes may be connected to the first terminal, so that the first electrodes may have a positive polarity. The second electrodes may be connected to the second terminal, so that the second electrodes may have a negative polarity. The electrostatic chuck 100 may receive a voltage from the power supply 500 to generate an electrostatic force.

The cooling plate 600 may be disposed over the electrostatic chuck 100. A driving unit may be disposed between the cooling plate 600 and the vacuum chamber VC. The cooling plate 600 may move in the third direction DR3 or the direction opposite to the third direction DR3 by an operation of the driving unit. For example, the cooling plate 600 may move vertically by the operation of the driving unit. The driving unit of the cooling plate 600 and the driving unit of the electrostatic chuck 100 may be provided separately from each other. Accordingly, deposition quality deterioration caused by vibrations of the cooling plate 600 may be inhibited or prevented.

The cooling plate 600 may include a cooling material. For example, the cooling plate 600 may include a cooling gas. The cooling gas may be argon gas or hydrogen gas. These example materials may be used alone or in combination with each other. The cooling plate 600 may be independently driven to control a temperature of the electrostatic chuck 100. The temperature of an entire area of the chucking surface of the electrostatic chuck 100 may be controlled to be uniform and constant, so that strain of the substrate SUB caused by a temperature deviation may be reduced or prevented.

The magnetic plate 700 may be disposed over the cooling plate 600. A driving unit may be disposed between the magnetic plate 700 and the vacuum chamber VC. The driving unit of the cooling plate 600 and the driving unit of the magnetic plate 700 may be a same device, or may be separate devices. In case that the driving unit of the cooling plate 600 and the driving unit of the magnetic plate 700 are separate devices, the driving unit of the cooling plate 600 and the driving unit of the magnetic plate 700 may be controlled simultaneously. In an embodiment, the driving unit of the cooling plate 600 and the driving unit of the magnetic plate 700 may be controlled separately from each other. In a case that the driving unit of the magnetic plate 700 and the driving unit of the electrostatic chuck 100 are provided separately from each other, deterioration of a deposition quality caused by vibrations of the magnetic plate 700 may be reduced or prevented.

According to an embodiment, the holder (200) may include third connection parts 260. The third connection parts 260 may be rotationally movable, and the holder 200 including the third connection parts 260 and the substrate SUB may not overlap each other. For example, the third connection parts 260 may be disposed at a position offset from the substrate SUB. Accordingly, a dead space, which is a portion of the substrate SUB overlapping the holder 200 in a plan view, may not exist, and an effective area of a cell arrangement may be increased.

FIG. 9 is a view illustrating the pixel manufactured by the deposition device of FIG. 7.

Referring to FIG. 9, the pixel PX may include a base substrate BS, a buffer layer BFR, a transistor TR, a gate insulating layer GI, an interlayer insulating layer ILD, a via insulating layer VIA, a light emitting element EL, and a pixel defining layer PDL. The transistor may include an active layer ACT, a gate electrode GE, a source electrode SE, and a drain electrode DE. The light emitting element EL may include a first electrode AE, a light emitting layer EML, and a second electrode CE. The display area DA may include an emission area PA and a non-emission area NPA. The transistor TR and the light emitting element EL may be disposed in the emission area PA. The non-emission area NPA may be adjacent to the emission area PA in a plan view. For example, the non-emission area NPA may surround the emission area PA in a plan view. Here, plan view may mean when viewed in the third direction DR3.

The base substrate BS may include glass, quartz, or plastic. In an embodiment, the base substrate BS may have flexible, bendable, or rollable characteristics.

The buffer layer BFR may be disposed on the base substrate BS. The buffer layer BFR may include an inorganic insulating material. For example, the buffer layer BFR may include silicon oxide, silicon nitride, or silicon oxynitride. The buffer layer BFR may serve to inhibit or block impurities so that the active layer ACT of the transistor TR may not be damaged by the impurities diffused from the base substrate BS.

The active layer ACT may be disposed on the buffer layer BFR. In an embodiment, the active layer ACT may include a silicon semiconductor. For example, the active layer ACT may include amorphous silicon or polycrystalline silicon. In another embodiment, the active layer ACT may include an oxide semiconductor. For example, the active layer ACT may include zinc oxide, zinc-tin oxide, zinc-indium oxide, indium oxide, titanium oxide, indium-gallium-zinc oxide, or indium-zinc-tin oxide.

The gate insulating layer GI may be disposed on the active layer ACT. The gate insulating layer GI may include an inorganic insulating material. For example, the gate insulating layer GI may include silicon oxide, silicon nitride, silicon oxynitride, titanium oxide, or tantalum oxide. The gate insulating layer GI may serve to electrically insulate the active layer ACT and the gate electrode GE from each other.

The gate electrode GE may be disposed on the gate insulating layer GI. The gate electrode GE may include a conductive material. For example, the gate electrode GE may include a metal, an alloy, a conductive metal oxide, or a transparent conductive material. A gate signal may be applied to the gate electrode GE. The gate signal may turn on or turn off the transistor TR and adjust electrical conductivity of the active layer ACT.

The interlayer insulating layer ILD may be disposed on the gate electrode GE. The interlayer insulating layer ILD may include an organic insulating material and/or an inorganic insulating material. The interlayer insulating layer ILD may electrically insulate the source electrode SE and drain electrode DE from the gate electrode GE.

The source electrode SE and the drain electrode DE may be disposed on the interlayer insulating layer ILD. Each of the source electrode SE and the drain electrode DE may include a conductive material. For example, each of the source electrode SE and the drain electrode DE may include a metal, an alloy, a conductive metal oxide, or a transparent conductive material. Each of the source electrode SE and the drain electrode DE may electrically contact the active layer ACT through a contact hole passing through the interlayer insulating layer ILD and the gate insulating layer GI.

The via insulating layer VIA may be disposed on the source electrode SE and the drain electrode DE. The via insulating layer VIA may include an organic insulating material. For example, the via insulating layer VIA may include a poly-acrylic resin, a polyimide resin, or an acrylic resin. Accordingly, a top surface of the via insulating layer VIA may be substantially flat.

The first electrode AE may be disposed on the via insulating layer VIA. The first electrode AE may include a conductive material. For example, the first electrode AE may include a metal, an alloy, a conductive metal oxide, or a transparent conductive material. The first electrode AE may electrically contact the source electrode SE or the drain electrode DE through a contact hole penetrating the via insulating layer VIA. In an embodiment, the first electrode AE may be referred to as an anode electrode.

The pixel defining layer PDL may be disposed on the first electrode AE. The pixel defining layer PDL may include an organic insulating material. For example, the pixel defining layer PDL may include a polyacryl-based compound or a polyimide-based compound. The pixel defining layer PDL may partition the emission area PA of each of the pixels PX. The pixel defining layer PDL may include a pixel opening exposing the first electrode AE.

The light emitting layer EML may be disposed on the first electrode AE in the pixel opening. The light emitting layer EML may include an organic light emitting material. In an embodiment, the light emitting layer EML may have a multi-layer structure including various functional layers. In an embodiment, the light emitting layer EML may include at least one of a hole injection layer, a hole transport layer, an electron transport layer, or an electron injection layer.

The second electrode CE may be disposed on the light emitting layer EML and may cover the pixel defining layer PDL. In an embodiment, the second electrode CE may be referred to as a cathode electrode.

In an embodiment, the light emitting layer EML may be formed by depositing a deposition material on the first electrode AE. In this case, the deposition device (e.g., the deposition device 1000 of FIG. 7) may be used.

However, the disclosure is not limited thereto, and a layer formed of the deposition material may not be limited as long as the layer is formed by the deposition process. For example, the deposition process may include a sputtering process. The layer that may be deposited may be a functional layer such as a hole transport layer or an electron transport layer, or may be a capping layer or an encapsulation layer disposed on the second electrode CE. The deposition materials may include an organic material and/or an inorganic material.

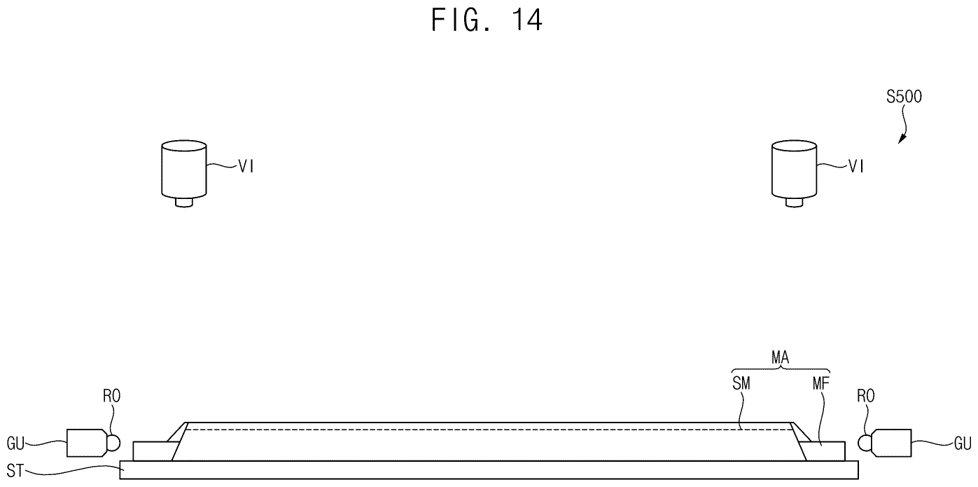

FIG. 10, FIG. 11, FIG. 12, FIG. 13, and FIG. 14 are views illustrating an example manufacturing method of a mask using a mask manufacturing device of FIG. 1. Hereinafter, descriptions that overlap with the description of the mask manufacturing device described above with reference to FIG. 1 through FIG. 5 may be omitted or simplified.

Referring to FIG. 10 through FIG. 14, an example manufacturing method of a mask according to an embodiment of the disclosure may include disposing the mask frame MF on the stage ST in which the air hole AH is defined (S100), levitating the mask frame MF above the stage ST by the air exiting from the air hole AH (S200), checking an alignment of the mask frame MF (S300), restricting a horizontal movement of the mask frame MF by the guide GU disposed on the side of the mask frame MF and including the roller RO at the end portion of the guide GU facing the side of the mask frame MF (S400), and seating the stick mask SM on the mask frame MF and fixing the stick mask SM to the mask frame MF (S500).

As depicted in FIG. 10 and FIG. 11, in an embodiment, the mask frame MF may be disposed on the stage ST in which the air hole AH is defined (S100), and the mask frame MF may be levitated above the stage ST by the air exiting from the air hole AH (S200).

As the mask frame MF is levitated above the stage ST, friction between the stage ST and the mask frame MF may be reduced or eliminated, and an effect of the flatness of the upper surface of the stage ST may be reduced or removed. Accordingly, the manufacturing precision of the mask (e.g., the mask MA of FIG. 1) may be improved. Further, in a case that an air pocket is omitted from the mask frame MF, an effect of the flatness of the mask frame MF may be reduced or eliminated.

As depicted in FIG. 12. in an embodiment, the alignment of the mask frame MF may be checked (S300). The alignment of the mask frame MF may be checked by the alignment camera VI, and the guide GU may be disposed so that the mask frame MF may be positioned within an imaging area R1 of the alignment camera VI.

Accordingly, a decrease in the manufacturing precision of the mask due to the mask frame MF moving within or escaping from the imaging area R1 of the alignment camera VI may be reduced or prevented.

As depicted in FIG. 13, in an embodiment, the horizontal movement of the mask frame MF may be restricted by the guide GU disposed on the side of the mask frame MF and including the roller RO at the end of the guide GU facing the side of the mask frame MF (S400).

In an embodiment, as described with reference to FIG. 3, the roller RO may include the ball caster.

In an embodiment, as described above with reference to FIG. 4, the mask frame MF may include the first side EP1, the second side EP2 substantially parallel to the first side EP1, the third side EP3 crossing the first side EP1 and the second side EP2, and the fourth side EP4 substantially parallel to the third side EP3, and the guide GU may include the first guide GU1 disposed adjacent to the first side EP1 of the mask frame MF, the second guide GU2 disposed adjacent to the second side EP2 of the mask frame MF, the third guide GU3 disposed adjacent to the third side EP3 of the mask frame MF, the fourth guide GU4 disposed adjacent to the fourth side EP4 of the mask frame MF. In an embodiment, the first guide GU1 and the second guide GU2 may restrict the movement of the mask frame MF in the first direction, and the third guide GU3 and the fourth guide GU may restrict the movement of the mask frame MF in the second direction.

As the guide GU includes the roller RO, the friction between the guide GU and the mask frame MF when aligning the mask frame MF may be reduced or eliminated.

As depicted in FIG. 14, in an embodiment, the mask frame MF may be lowered onto the stage ST in an aligned state, for example, by turning off the air exiting the air holes AH defined in the stage ST. The stick mask SM may be disposed on the mask frame MF, and the stick mask SM may be fixed to the mask frame MF (S500). For example, the stick mask SM may be welded to the mask frame MF. In an embodiment, the guide GU may continue to restrict the horizontal movement of the mask frame MF even when the stick mask SM is fixed to the mask frame MF.

Accordingly, movement of the mask frame may be restricted and a manufacturing precision of the mask may be maintained.

According to an embodiment, the levitating of the mask frame MF may be performed, the guides GU may ensure an alignment, the alignment camera VI may check the alignment, and the stick mask SM may be fixed to the mask frame MF. In a case where friction between components is reduced or eliminated, this a process of levitating the mask frame MF and checking the alignment may be reliably performed, and iterations of the process may be avoided. For example, the alignment may be reliably maintained during placement of the mask frame MF. Accordingly, processing time may be reduced in a case where successful alignment is achieved in about one to two attempts for stick mask SM.

In addition, a manufacturing difference or tolerance between different masks MA may be reduced by reducing an effect due to friction (e.g., using air floating in the vertical direction and rotating by the roller RO in the horizontal direction) and an effect due to the flatness of stage ST (e.g., a level difference of stage ST of FIG. 6).

A mask manufacturing device according to embodiments of the present invention may be applied to a process of manufacturing display devices included in, for example, computers, laptops, mobile phones, smartphones, smart pads, PMPs, PDAs, or MP3 players.

The present disclosure should not be construed as being limited to embodiments set forth herein. Rather, embodiments are provided so that this present disclosure will be thorough and complete and will fully convey the concept of the present disclosure to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask manufacturing device comprising:
a stage for supporting a mask frame; and
a guide disposed at a side of the mask frame, restricting a horizontal movement of the mask frame, and including a roller disposed at an end portion of the guide facing the mask frame.

2. The mask manufacturing device of claim 1, wherein the roller includes a ball caster.

3. The mask manufacturing device of claim 1, wherein,
the mask frame includes a first side, a second side parallel to the first side, a third side crossing both the first side and the second side, and a fourth side parallel to the third side, and
the guide includes a first guide disposed adjacent to the first side, a second guide disposed adjacent to the second side, a third guide disposed adjacent to the third side, and a fourth guide disposed adjacent to the first side.

4. The mask manufacturing device of claim 3, wherein,
the first guide and the second guide restrict a movement of the mask frame in a first direction within a first predetermined gap, and
the third guide and the fourth guide restrict a movement of the mask frame in a second direction crossing the first direction within a second predetermined gap.

5. The mask manufacturing device of claim 1, further comprising a plurality of air holes defined in the stage for directing air to the mask frame and for levitating the mask frame above the stage.

6. The mask manufacturing device of claim 5, further comprising:
an alignment camera disposed above the stage.

7. The mask manufacturing device of claim 6, wherein the alignment camera is configured to check an alignment of the mask frame while the mask frame is levitated.

8. The mask manufacturing device of claim 1, wherein a stick mask is disposed on the mask frame wherein the stick mask includes:
a pattern portion on which a plurality of cell regions is defined, and
a dummy portion surrounding the pattern portion.

9. A mask manufacturing device comprising:
a stage having a plurality of air holes disposed in an edge portion of an upper surface of the stage;
a plurality of guides disposed overlapping a plurality of sides of the stage and forming a restrictive space above the stage; and
a plurality of rollers disposed at end portions of the plurality of guides and facing the restrictive space.

10. The mask manufacturing device of claim 9, wherein the rollers each include a ball caster.

11. The mask manufacturing device of claim 9, further comprising:
an alignment camera disposed above the stage,
wherein the alignment camera is configured to check an alignment of a mask frame while the mask frame is levitated within the restrictive space.

12. A manufacturing method of a mask, the method comprising:
disposing a mask frame on a stage in which an air hole is defined;
levitating the mask frame above the stage by air exiting from the air hole; and
restricting a horizontal movement of the mask frame by a guide disposed on a side of the mask frame and including a roller disposed at an end portion of the guide facing the side of the mask frame.

13. The method of claim 12, wherein the roller includes a ball caster rolling in contact with the mask frame.

14. The method of claim 12, wherein,
the mask frame includes a first side, a second side parallel to the first side, a third side crossing both the first side and the second side, and a fourth side parallel to the third side, and
the guide includes a first guide disposed adjacent to the first side, a second guide disposed adjacent to the second side, a third guide disposed adjacent to the third side, and a fourth guide disposed adjacent to the first side,
wherein the method further comprising directing the air from a plurality of holes, including the air hole, defined in the stage, to each of the first side, the second side, the third side, and the fourth side of the mask frame.

15. The method of claim 14, further comprising:
restricting, by the first guide and the second guide, a movement of the mask frame in a first direction within a first predetermined gap, and
restricting, by the third guide and the fourth guide, a movement of the mask frame in a second direction crossing the first direction within a second predetermined gap.

16. The method of claim 12, further comprising:
checking an alignment of the mask frame after levitating the mask frame above the stage.

17. The method of claim 16, wherein,
the alignment of the mask frame is checked by an alignment camera, and
the guide is disposed so that the mask frame is positioned within an imaging area of the alignment camera.

18. The method of claim 12, further comprising:
seating a stick mask on the mask frame after levitating the mask frame from the stage.

19. The method of claim 18, further comprising:
welding the stick mask to the mask frame after seating the stick mask on the mask frame.

20. The method of claim 19, maintaining a position of the guide following the welding of the stick mask to the mask frame.
